(19) United States
(12) Patent Application Publication
(10) Pub. No.: US 2008/0128867 A1
(43) Pub. Date: Jun. 5, 2008

(54) METHOD FOR FORMING MICRO-PATTERN IN A SEMICONDUCTOR DEVICE

(76) Inventor: Sang-Uk Lee, Seoul (KR)

Correspondence Address: SHERR & NOURSE, PLLC, 620 HERNDON PARKWAY, SUITE 200, HERNDON, VA, 20170, US

(21) Appl. No.: 11/782,178

(22) Filed: Jul. 24, 2007

(30) Foreign Application Priority Data
Dec. 5, 2006 (KR) 10-2006-0121938

(51) Int. Cl. H01L 21/31; H01L 23/58

(52) U.S. Cl. 257/629; 438/759; 257/E21.259; 257/E23.114

(57) ABSTRACT

A method of forming a micro-pattern in a semiconductor device that is less than approximately 130 nm using the KrF exposure equipment. A method of forming a micro-pattern in a semiconductor device includes at least one of the following steps: Forming an etching layer, a hard mask layer, an organic bottom anti-reflection (BARC) layer, and/or a photoresist film on and/or over a semiconductor substrate. Forming a photoresist pattern by exposing and developing the photoresist film. Forming a BARC layer pattern using the photoresist pattern as a mask. Forming a hard mask layer pattern using the BARC layer pattern as an etch mask. Forming an etching layer pattern by using the hard mask layer pattern as an etch mask.

The present application claims priority under 35 U.S.C. 119 to Korean Patent Application No. 10-2006-0121938 (filed on Dec. 5, 2006), which is hereby incorporated by reference in its entirety.

### BACKGROUND

Aspects of semiconductor technology have focused on increasing the integration of semiconductor devices (e.g. achieving smaller scale devices). Micro-patterning technology has also developed as part of the development of aspects of semiconductor technology. Additionally, the formation processes of photoresist film patterns may play an important role in some manufacturing processes of some semiconductor devices.

As semiconductor devices become more integrated, the minimum size of patterns may decrease. In some applications, a required size of a pattern may be smaller than the resolution capability of exposure equipment. Accordingly, it be necessary to use equipment having relatively high resolution light sources to form micro-patterns that are a relatively small size. For example, KrF exposure equipment having a wavelength around 248 nm may not be capable of forming micro-patterns that are 130 nm or less. Accordingly, ArF exposure equipment (193 nm) may need to be used due to it's relatively high resolution capabilities. Since ArF exposure equipment (193 nm) may be relatively expensive, it may be prohibitively expensive to use ArF exposure equipment (193 nm) in some semiconductor processes.

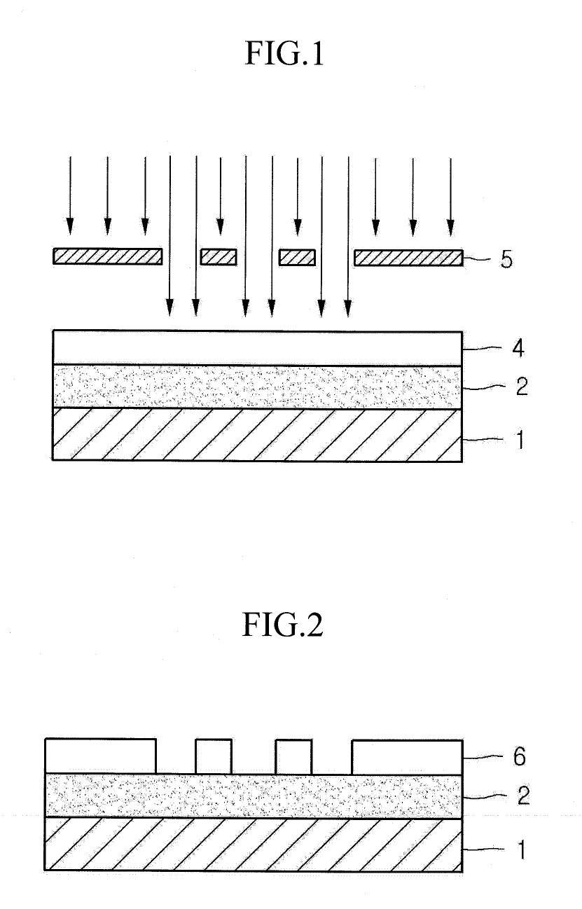

Example FIGS. 1 to 3 illustrate a method of forming micro-patterns in semiconductor devices. As illustrated in FIG. 1, etching layer 2 and photoresist film 4 may be formed over semiconductor substrate 1. An exposed area of photoresist film 4 may be selectively exposed through exposure mask 5 to light from KrF exposure equipment (248 nm).

As illustrated in example FIG. 2, the exposed area may be developed to remove the exposure area to form photoresist pattern 6. Photoresist pattern 6 may be formed using KrF exposure equipment (248 nm), which may limit the resolution capability (e.g. limit the resolution capability to 130 nm). In other words, photoresist pattern 6 may be limited to dimensions that are above 130 nm.

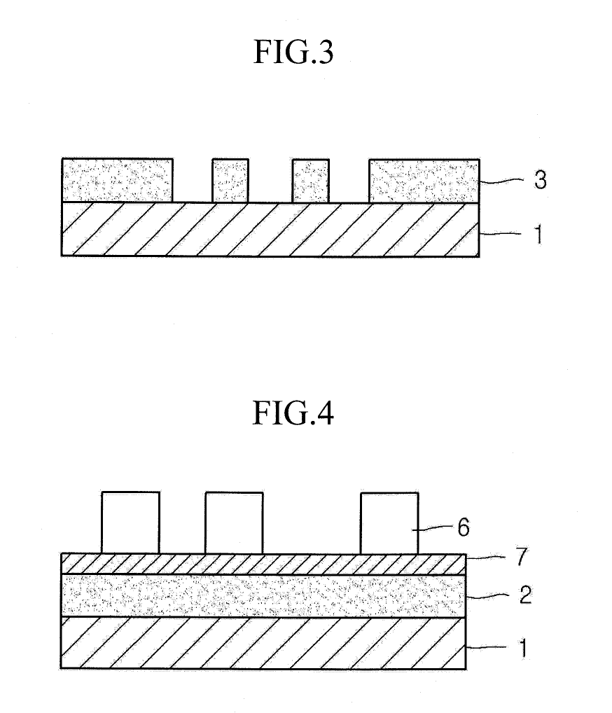

As illustrated in example FIG. 3, etching layer 2 (under photoresist pattern 6) may be etched using photoresist pattern 6 as an etch mask to form etching layer pattern 3. Since the photoresist pattern 6 may be limited to dimensions greater than approximately 0.13 μm, etching layer pattern 3 may be limited to dimensions greater than approximately 130 nm. Accordingly, it may be difficult to form micro-pattern having dimensions less than approximately 130 nm using KrF exposure equipment (248 nm).

As illustrated in example FIG. 4, photoresist pattern 6 may be formed by interposing an organic bottom anti-reflection layer (BARC) 7 between etching layer 2 and photoresist film 4. Unfortunately, it may be relatively difficult to dissolve BARC 7 in an alkalic developing solution that dissolves photoresists in a lithography process.

### SUMMARY

Embodiments relate to a method of forming a micro-pattern in a semiconductor device that is less than approximately 130 nm using the KrF exposure equipment. Embodiments relate to a method of forming a micro-pattern in a semiconductor device including at least one of the following steps: Forming an etching layer, a hard mask layer, an organic bottom anti-reflection (BARC) layer, and/or a photoresist film on and/or over a semiconductor substrate. Forming a photoresist pattern by exposing and developing the photoresist film. Forming a BARC layer pattern using the photoresist pattern as a mask. Forming a hard mask layer pattern using the BARC layer pattern as an etch mask. Forming an etching layer pattern by using the hard mask layer pattern as an etch mask.

### DRAWINGS

Example FIGS. 1 to 4 illustrate a method of forming a micro-pattern in a semiconductor device.

Example FIGS. 5 to 10 illustrate a method of forming a micro-pattern in a semiconductor device, according to embodiments.

### DESCRIPTION

As illustrated in example FIG. 5, etching layer 20 may be formed on and/or over semiconductor substrate 10. Hard mask layer 30 may be formed on and/or over etching layer 20. Organic bottom anti-reflection layer 40 may be formed on and/or over hard mask layer 30. Photoresist film 50 may be formed on and/or over semiconductor substrate 10. In embodiments, etching layer 20 may include a conductive layer, which may include metal and/or polysilicon, and may have a thickness between approximately 2000 Å and approximately 3000 Å. Hard mask layer 30 may serve as a hard mask during an etching process. In embodiments, hard mask layer 30 may include at least one of a silicon nitride layer, a nitride layer, and an oxide nitride layer.

Organic bottom anti-reflection layer (BARC) 40 may prevent differences in critical dimensions caused by light diffracted and/or reflected light from semiconductor substrate 10 during a manufacturing process. An organic material may absorb light from a light source and may be coated over semiconductor substrate 10 to prevent light from being reflected from semiconductor substrate 10.

In embodiments, BARC layer 40 may include a wet BARC layer, which may be dissolved in an alkalic developing solution that also dissolves photoresist. BARC layer 40 may be isotropically dissolved in an alkalic developing solution, in accordance with embodiments. The degree of isotropic dissolution of BARC layer 40 may be controlled by controlling the temperature of a bake after coating an anti-reflection layer composition, in accordance with embodiments. If the temperature of a bake exceeds the predetermined temperature, then BARC layer 40 may not be dissolved or inadequately dissolved in a alkalic developing solution, in accordance with embodiments. If the temperature of a bake is too low, then the degree of dissolution of BARC layer 40 may be too high.

According to embodiments, after coating an anti-reflection layer composition, a baking process may be performed at a predetermined temperature for a predetermined period of time so that BARC layer 40 can be dissolved in the alkalic developing solution in a controlled manner. In embodiments, BARC layer 40 may have a thickness between approximately 500 Å and approximately 1500 Å. An exposure process may be performed using KrF exposure equipment (248 nm) on photoresist film 50, according to embodiments. The exposure area of photoresist film 50 may be removed by a developing process using an alkalic developing solution to form photoresist film pattern 51, in accordance with embodiments.

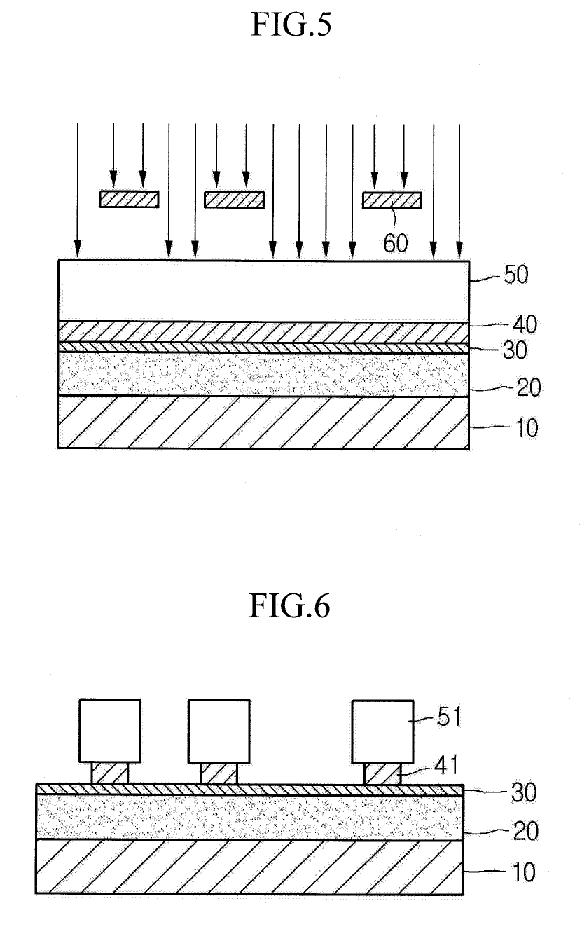

As illustrated in example FIG. 6, KrF exposure equipment (248 nm) may form a micro-pattern having the size of approximately 130 nm or larger, in accordance with embodiments. Accordingly, photoresist film pattern 51 may be formed having dimensions of approximately 130 nm or larger, in accordance with embodiments. BARC layer 40 that may be formed under photoresist film 50 may be dissolved in an alkalic developing solution that develops photoresist film pattern 51, in accordance with embodiments. In embodiments, BARC layer 40 may be etched at the same time that photoresist film 50 is developed, to form BARC layer pattern 41.

In embodiments, since the BARC layer 40 is isotropically etched, BARC layer pattern 41 may have dimensions less than dimensions of photoresist film pattern 51 (e.g. less than 130 nm). In embodiments, since BARC layer 40 is isotropically dissolvable, the portion of BARC layer 40 formed under the exposure area of photoresist film 50 may etched by an alkailic developing solution. Further, a portion of BARC layer 40 under photoresist film pattern 51 may be etched on the sides to form BARC layer pattern 41, in accordance with embodiments. BARC layer pattern 41 may have lateral dimensions less than the lateral dimensions of photoresist film pattern 51 due to the etching of the sides of BARC layer 40 that are under photoresist film pattern 51, in accordance with embodiments. In embodiments, BARC layer pattern 41 may have dimensions between approximately 70 nm and 120 nm, which are less than the dimensions of photoresist film pattern 51. In embodiments, BARC layer pattern 41 may have dimensions of approximately 80 nm. One of ordinary skill in the art would appreciate other dimensions.

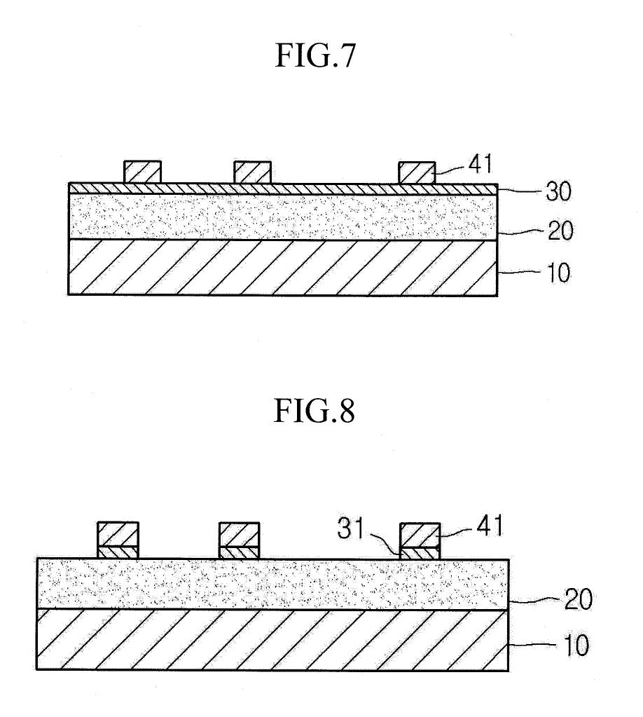

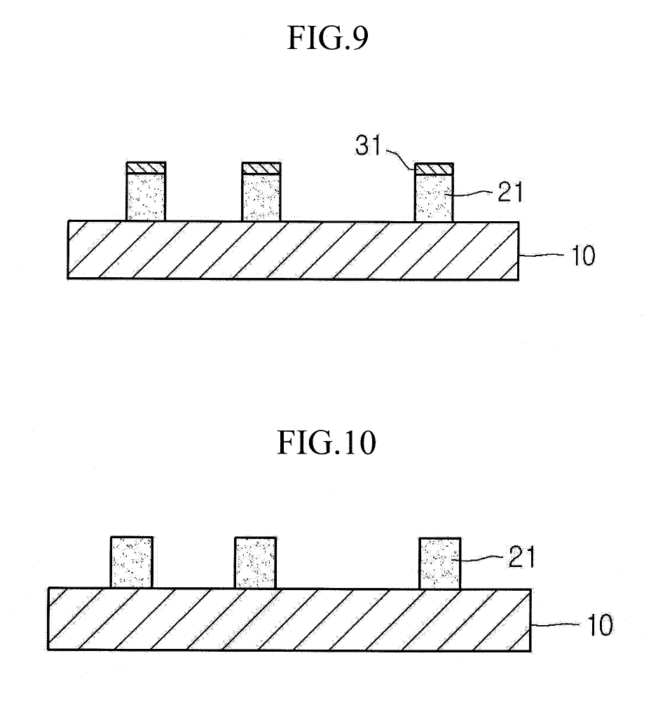

As illustrated in example FIG. 7, photoresist film pattern 51 may be removed (e.g. removed by a thinner), which may result in BARC layer pattern 41 having dimensions less than 130 nm (e.g. approximately 80 nm). As illustrated in example FIG. 8, hard mask layer 30 under the BARC layer pattern 41 may be etched by using BARC layer pattern 41 as an etch mask to form hard mask layer pattern 31, in accordance with embodiments. In embodiments, hard mask layer pattern may have dimensions less than 130 nm (e.g. approximately 80 nm). As illustrated in example FIG. 9, when BARC layer pattern 41 is removed, a hard mask layer pattern 31 may remain, in accordance with embodiments. In embodiments, the dimensions of hard mask layer pattern 31 may be less than 130 nm (e.g. approximately 80 nm). Etching layer 20 formed under the hard mask layer pattern 31 may be etched using the hard mask layer pattern 31 as an etch mask to form etching layer pattern 21, in accordance with embodiments. In embodiments, dimensions of etching layer pattern 21 may be less than 130 nm (e.g. approximately 80 nm). As illustrated in example FIG. 10, hard mask pattern 31 may be removed, so that etching layer pattern 21 (e.g. a micro pattern) remains on and/or over semiconductor substrate 10.

Embodiments relate to a method of forming a micro-pattern in a semiconductor device. In embodiments, side portions of a BARC layer under a photoresist layer may be dissolved in an alkalic developing solution to form a BARC layer pattern with dimension less than the lithography resolution of the light source used (e.g. KrF exposure equipment). Accordingly, a micro-patterns with dimensions less than 130 nm can be formed using KrF exposure equipment. In embodiment, a hard mask layer and an etching layer may be etched by using a BARC layer pattern to govern the dimensions of a hard mask layer pattern and an etching layer pattern. Accordingly, ultra micro-patterns may be formed using KrF exposure equipment, in accordance with embodiments. In embodiments where micro-pattern can be formed using KrF exposure equipment, manufacturing costs for semiconductor devices may be minimized, thus rewarding both manufacturers and consumers of semiconductor products.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a organic bottom anti-reflection layer over a semiconductor substrate;
forming a photoresist pattern over the organic bottom anti-reflection layer; and
etching side portions of the organic bottom anti-reflection layer under the photoresist pattern to form a bottom anti-reflection layer pattern.

2. The method of claim 1, wherein dimensions of elements of said bottom anti-reflection layer pattern are less than dimensions of elements of the photoresist pattern.

3. The method of claim 2, wherein:
the dimensions of elements the photoresist pattern are approximately 130 nm; and
the dimensions of elements of said bottom anti-reflection layer pattern are between approximately 70 nm and approximately 120 nm.

4. The method of claim 3, wherein the dimensions of elements of said bottom anti-reflection layer pattern are approximately 80 nm.

5. The method of claim 1, comprising:
forming a hard mask layer over the semiconductor substrate, prior to said forming the organic bottom anti-reflection layer; and
etching the hard mask layer to form a hard mask layer pattern using the organic bottom anti-reflective layer pattern as an etch mask.

6. The method of claim 5, wherein the hard mask layer comprises at least one of an oxide layer, a nitride layer, and an oxide nitride layer.

7. The method of claim 5, comprising:
forming an etching layer over the semiconductor substrate, prior to said forming the hard mask layer; and
etching the etching layer to form an etching layer pattern using the hard mask layer pattern as an etch mask.

8. The method claim 7, wherein the etching layer comprises at least one metal and polysilicon.

9. The method of claim 1, comprising forming a photoresist film over the organic bottom anti-reflective layer, wherein:
predefined areas of the photoresist film are exposed to light from a light source;
the predefined areas are developed using a solution; and
said etching side portions of the organic bottom anti-reflection layer are etched by the solution.

10. The method of claim 9, wherein the light source illuminates light at a wavelength of approximately 248 nm.

11. The method of claim 10, wherein the light source is KrF exposure equipment.

12. The method of claim 9, wherein the solution is a alkalic developing solution.

13. The method of claim 9, wherein the redefined areas are developed and said etching side portions are performed in a same processing step.

14. The method of claim 9, wherein said etching side portions is isotropically etching.

15. The method of claim 1, wherein the organic bottom anti-reflection layer comprises a wet organic bottom anti-reflection layer.

16. An apparatus comprising:
a bottom anti-reflection layer pattern formed over a semiconductor substrate;
a photoresist pattern formed over the organic bottom anti-reflection layer pattern, wherein dimensions of elements of the photoresist pattern are larger than dimensions of elements of the bottom anti-reflection layer pattern under respective elements of the photoresist pattern.

17. The apparatus of claim 16, wherein:
the dimensions of elements the photoresist pattern are approximately 130 nm; and
the dimensions of elements of said bottom anti-reflection layer are between approximately 70 nm and approximately 120 nm.

18. The apparatus of claim 17, wherein the dimensions of elements of said bottom anti-reflection layer are approximately 80 nm.

19. The apparatus of claim 16, comprising a hard mask layer pattern formed over the semiconductor substrate and below said bottom anti-reflection layer pattern.

20. The apparatus of claim 19, comprising an etching layer formed over the semiconductor substrate and below the hard mask layer pattern.
